(19) United States
(12) Patent Application Publication
(10) Pub. No.: US 2026/0150463 A1
(43) Pub. Date: May 28, 2026

(54) DISPLAY DEVICE AND METHOD OF MANUFACTURING THE SAME

(71) Applicant: LG DISPLAY CO., LTD., Seoul (KR)

(72) Inventors: Su-Min LEE, Paju-si (KR); Byung-Hyun LEE, Paju-si (KR); Dae-Young SEO, Paju-si (KR); Tae-Yong KIM, Paju-si (KR)

(73) Assignee: LG DISPLAY CO., LTD., Seoul (KR)

(21) Appl. No.: 19/325,255

(22) Filed: Sep. 10, 2025

(30) Foreign Application Priority Data
Nov. 22, 2024 (KR) 10-2024-0168018

(51) Int. Cl. H10H 29/49; H10H 29/01; H10H 29/39

(52) U.S. Cl. CPC H10H 29/49; H10H 29/012; H10H 29/39

(57) ABSTRACT

A display device and a method for manufacturing the same are discussed. The display device includes a first substrate, a thin film transistor over an inner surface of the first substrate, a second substrate spaced apart from the first substrate, a light-emitting element over an inner surface of the second substrate facing the first substrate and including a first element electrode and a second element electrode, and first and second assembly lines between the second substrate and the light-emitting element. The first element electrode is electrically connected to the first and second assembly lines, and the second element electrode is electrically connected to the thin film transistor.

### CROSS-REFERENCE TO RELATED APPLICATION

The present application claims priority to Korean Patent Application No. 10-2024-0168018, filed in the Republic of Korea on Nov. 22, 2024, the entire contents of which are hereby expressly incorporated by reference into the present application.

### BACKGROUND

### Technical Field

The present disclosure relates to a display device, and more particularly, to a display device including a light-emitting element and a method of manufacturing the same.

### Discussion of the Related Art

As the information society progresses, a demand for different types of display devices increases, and flat panel display devices (FPD) such as liquid crystal display devices and light-emitting diode display devices have been developed and applied to various fields.

Among the flat panel display devices, light-emitting diode display devices emit light due to the radiative recombination of an exciton. The exciton is formed from an electron and a hole by injecting charges into a light-emitting layer between a cathode for injecting electrons and an anode for injecting holes in a light-emitting diode.

The light-emitting diode display device can offer various advantages and improved properties. For instance, compared to the liquid crystal display device, because it is self-luminous, the light-emitting diode display device has a wide viewing angle, and since a backlight unit is not required, the light-emitting diode display device has an ultra-thin thickness and light weight. In addition, the light-emitting diode display device is also advantageous in power consumption.

The light-emitting diode display device can include inorganic-based light-emitting elements or organic-based light-emitting elements. The inorganic-based light-emitting elements have relatively excellent stability, fast response characteristics, and high contrast ratios, and micro light-emitting diodes (micro LEDs or uLED) are widely used as the inorganic-based light-emitting elements for high resolution.

The inorganic-based light-emitting elements can be formed on a separate growth substrate and transferred to an array substrate of a display device. However, since a pitch of the light-emitting elements on the growth substrate is different from a pitch of the light-emitting elements on the array substrate, in order to transfer the light-emitting elements on the growth substrate to the array substrate, complex transfer steps using a plurality of stamps may be needed.

### SUMMARY OF THE DISCLOSURE

Accordingly, embodiments of the present disclosure are directed to a display device that substantially obviates one or more of the problems due to limitations and disadvantages of the related art.

An aspect of the present disclosure is to provide a display device capable of reducing or minimizing the transfer steps of a light-emitting element.

Additional features and aspects will be set forth in the description that follows, and in part will be apparent from the description, or can be learned by practice of the inventive concepts provided herein. Other features and aspects of the inventive concepts can be realized and attained by the structure particularly pointed out in the written description, or derivable therefrom, and the claims hereof as well as the appended drawings.

To achieve these and other aspects of the inventive concepts, as embodied and broadly described herein, a display device according to aspects of the present disclosure includes a first substrate; a thin film transistor over an inner surface of the first substrate facing a second substrate; the second substrate spaced apart from the first substrate; a light-emitting element over an inner surface of the second substrate facing the first substrate and including a first element electrode and a second element electrode; and first and second assembly lines between the second substrate and the light-emitting element, wherein the first element electrode is electrically connected to the first and second assembly lines, and the second element electrode is electrically connected to the thin film transistor.

In another aspect of the present disclosure, a method of manufacturing a display device includes forming a thin film transistor over a first substrate; forming first and second assembly lines over a second substrate; forming a second insulation layer over the first and second assembly lines and having an assembly hole; transferring a light-emitting element in the assembly hole, the light-emitting element including a first element electrode and a second element electrode; forming a connection electrode contacting the first element electrode and the first and second assembly lines; and attaching the first substrate provided with the thin film transistor and the second substrate provided with the connection electrode, wherein the first element electrode is electrically connected to the first and second assembly lines, and the second element electrode is electrically connected to the thin film transistor.

It is to be understood that both the foregoing general description and the following detailed description are examples and explanatory and are intended to provide further explanation of the inventive concepts as claimed.

### BRIEF DESCRIPTION OF THE DRAWINGS

The accompanying drawings, which are included to provide a further understanding of the disclosure and which are incorporated in and constitute a part of this application, illustrate embodiments of the disclosure and together with the description serve to explain various principles of the disclosure. In the drawings:

FIG. 1 is a view schematically showing a display device according to an embodiment of the present disclosure;

FIG. 2 is a schematic plan view of a display panel of a display device according to an embodiment of the present disclosure;

FIG. 3 is a schematic cross-sectional view of a display panel of a display device according to a first embodiment of the present disclosure;

FIG. 4 is a schematic view showing an optical path in the display panel of the display device according to the first embodiment of the present disclosure;

FIGS. 5A to 5F are schematic cross-sectional views of an assembly substrate of a display device for explaining the steps of manufacturing the display device according to the first embodiment of the present disclosure;

FIG. 6 is a schematic cross-sectional view of a display panel of a display device according to a second embodiment of the present disclosure;

FIG. 7 is a schematic view showing an optical path in the display panel of the display device according to the second embodiment of the present disclosure;

FIGS. 8A to 8F are schematic cross-sectional views of an assembly substrate of a display device for explaining the steps of manufacturing the display device according to the second embodiment of the present disclosure;

FIG. 9 is a schematic plan view of a display device according to a third embodiment of the present disclosure;

FIG. 10 is a schematic plan view enlarging area A1 of FIG. 9;

FIG. 11 is a schematic plan view of a display device according to a fourth embodiment of the present disclosure; and

FIG. 12 is a schematic plan view enlarging area A2 of FIG. 11.

### DETAILED DESCRIPTION OF THE EMBODIMENTS

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference numerals refer to the same components throughout this disclosure.

Further, in the following description of the present disclosure, when a detailed description of a known related art is determined to unnecessarily obscure the gist of the present disclosure, the detailed description thereof will be omitted herein or can be briefly discussed.

When terms such as “including,” “having,” “comprising” and the like mentioned in this disclosure are used, other parts can be added unless the term “only” is used herein.

Further, when a component is expressed as being singular, being plural is included unless otherwise specified.

In analyzing a component, an error range is interpreted as being included even when there is no explicit description.

In describing a positional relationship, for example, when a positional relationship of two parts/layers is described as being “over,” “on,” “above,” “below,” “under,” “next to,” or the like, one or more other parts/layers can be provided between the two parts/layers, unless the term “immediately” or “directly” is used therewith.

In describing a temporal relationship, for example, when a temporal predecessor relationship is described as being “after,” “subsequent,” “next to,” “prior to,” or the like, unless “immediately” or “directly” is used, cases that are not continuous or sequential can also be included.

As used herein, the terms “connected” and “coupled” are intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner. For example, the term “in contact with,” as used herein, encompasses both “indirect contact” and “direct contact.” Accordingly, when the phrase “A is in contact with B” is used, it implies that other components can be present between A and B, unless explicitly specified as “A is in direct contact with B.”

Although the terms such as ‘first’, ‘second,’ and the like are used to describe various components, these components are not substantially limited by these terms. These terms are used only to distinguish one component from another component, and may not define any order or sequence. Therefore, a first component described below can substantially be a second component within the technical spirit of the present disclosure. Further, the term “can” fully encompasses all the meanings and coverages of the term “may” and vice versa.

Features of various embodiments of the present disclosure can be partially or entirely united or combined with each other, technically various interlocking and driving are possible, and each of the embodiments can be independently implemented with respect to each other or implemented together in a related relationship.

Hereinafter, example embodiments of the present disclosure will be described in detail with reference to accompanying drawings. All the components of each display device/apparatus according to all embodiments of the present disclosure are operatively coupled and configured.

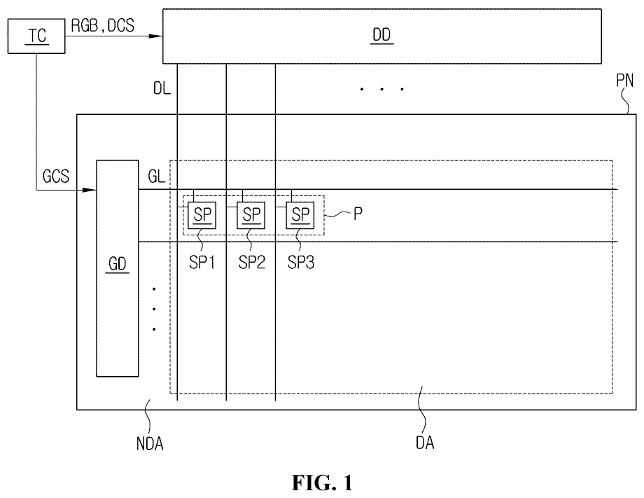

FIG. 1 is a view schematically showing a display device according to an embodiment of the present disclosure. The display device can be a micro LED (light-emitting diode) display device or a mini LED display device. However, embodiments of the present disclosure are not limited thereto, and in other embodiments, for example, the display device can be an organic light-emitting diode (OLED) display device.

Referring to FIG. 1, the display device according to an embodiment of the present disclosure can include a display panel PN, a timing controller TC, a data driver DD, and a gate driver GD.

The timing controller TC can generate image data RGB, a data control signal DCS, and a gate control signal GCS using an image signal and a plurality of timing signals, such as a data enable signal, a horizontal synchronization signal, a vertical synchronization signal, and a clock, transmitted from an external system such as a graphic card or a TV system.

In addition, the timing controller TC can transmit the generated image data RGB and the generated data control signal DCS to the data driver DD and can transmit the generated gate control signal GCS to the gate driver GD.

The data driver DD can generate a data voltage, which is a data signal, using the image data RGB and the data control signal DCS transmitted from the timing controller TC and can apply the generated data voltage to a data line DL of the display panel PN.

The gate driver GD can generate a gate voltage, which is a gate signal, using the gate control signal GCS transmitted from the timing controller TC and can apply the generated gate voltage to a gate line GL of the display panel PN.

Here, the gate driver GD can be provided as a gate-in-panel (GIP) type formed together on a substrate of the display panel PN on which the gate line GL, the data line DL, and sub-pixels SP are formed and can be disposed in a non-display area NDA.

In the embodiment of FIG. 1, the gate driver GD can be disposed on one side of the display panel PN, but in other embodiments, two gate drivers can be disposed on both sides of the display panel PN, respectively.

The display panel PN can include a display area DA displaying an image and a non-display area NDA surrounding the display area DA. The display panel PN can display the image using the gate voltage supplied from the gate driver GD and the data voltage supplied from the data driver DD. To do this, the display panel PN can include a plurality of pixel P, a plurality of gate lines GL, and a plurality of data lines DL disposed in the display area DA.

Each of the plurality of pixels P can include a plurality of sub-pixels SP and gate lines GL and the data lines DL can cross each other to define each pixel P and/or the sub-pixels SP. For example, each of the plurality of pixels P can include first, second, and third sub-pixels SP1, SP2, and SP3, and the first, second, and third sub-pixels SP1, SP2, and SP3 can be red, green, and blue sub-pixels, respectively.

At least one light-emitting diode, a plurality of thin film transistors, and at least one storage capacitor can be provided in each sub-pixel SP.

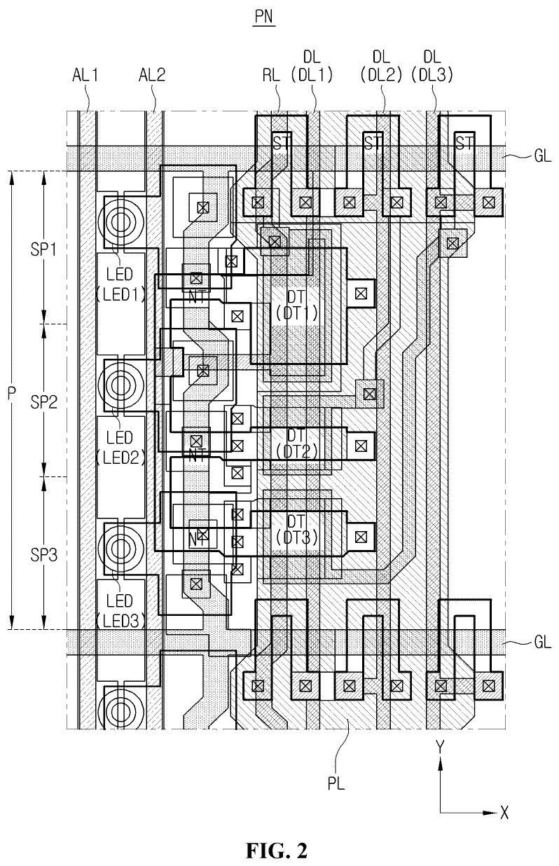

A planar configuration of a display device according to an embodiment of the present disclosure will be described with reference to FIG. 2.

FIG. 2 is a schematic plan view of a display panel of a display device according to an embodiment of the present disclosure and shows a pixel.

Referring to FIG. 2, in the display panel PN of the display device according to the embodiment of the present disclosure, a gate line GL can extend in a first direction X, and a data line DL can extend in a second direction Y. The data line DL can cross the gate line GL to define a pixel P, and the pixel P can include first, second, and third sub-pixels SP1, SP2, and SP3.

Here, the first, second, and third sub-pixels SP1, SP2, and SP3 can be arranged along the second direction Y. However, embodiments of the present disclosure are not limited thereto. In other embodiments, the first, second, and third sub-pixels SP1, SP2, and SP3 can be arranged in the first direction X.

The data line DL can include first, second, and third data lines DL1, DL2, and DL3, and the first, second, and third data lines DL1, DL2, and DL3 can be spaced apart from each other in the first direction X.

In addition, a reference line RL, a first power line PL, and first and second assembly lines AL1 and AL2 can be spaced apart from each other in the first direction X and can extend in the second direction Y to thereby cross the gate line GL.

The first, second, and third data lines DL1, DL2, and DL3 and the reference line RL can overlap the first power line PL, and the first and second assembly lines AL1 and AL2 can be spaced apart from the first power line PL. However, embodiments of the present disclosure are not limited thereto. In other embodiments, the first, second, and third data lines DL1, DL2, and DL3 and the reference line RL can be spaced apart from the first power line PL, and the first and second assembly lines AL1 and AL2 can overlap the first power line PL.

The data line DL can transmit a data voltage Vdata, and the reference line RL can transmit a reference voltage Vref. In addition, the first power line PL can transmit a high potential voltage VDD. The first and second assembly lines AL1 and AL2 can be a second power line and can transmit a low potential voltage VSS. However, embodiments of the present disclosure are not limited thereto. In other embodiments, the first power line PL can transmit a low potential voltage VSS, and the first and second assembly lines AL1 and AL2 can transmit a high potential voltage VDD.

A switching transistor ST can be provided at a crossing point of the gate line GL and each data line DL, a driving transistor DT can be connected to the switching transistor ST, and a light-emitting element LED can be connected to the driving transistor DT.

The driving transistor DT can be connected to the first power line PL, and the light-emitting element LED can be connected to the first and second assembly lines AL1 and AL2. The light-emitting element LED can be disposed between the first and second assembly lines AL1 and AL2.

The driving transistor DT can include first, second, and third driving transistors DT1, DT2, and DT3 provided at the first, second, and third sub-pixels SP1, SP2, and SP3, respectively. The light-emitting element LED can include first, second, and third light-emitting elements LED1, LED2, and LED3 provided at the first, second, and third sub-pixels SP1, SP2, and SP3, respectively.

The light-emitting element LED can be a micro light-emitting diode (micro LED or uLED) or a nano light-emitting diode (nano LED). For example, the first, second, and third light-emitting elements LED1, LED2, and LED3 can be red, green, and blue light-emitting diodes, respectively.

In addition, a sensing transistor NT and a storage capacitor can be further provided. The sensing transistor NT can be connected to the light-emitting element LED and the reference line RL, and the storage capacitor can be connected to the driving transistor DT.

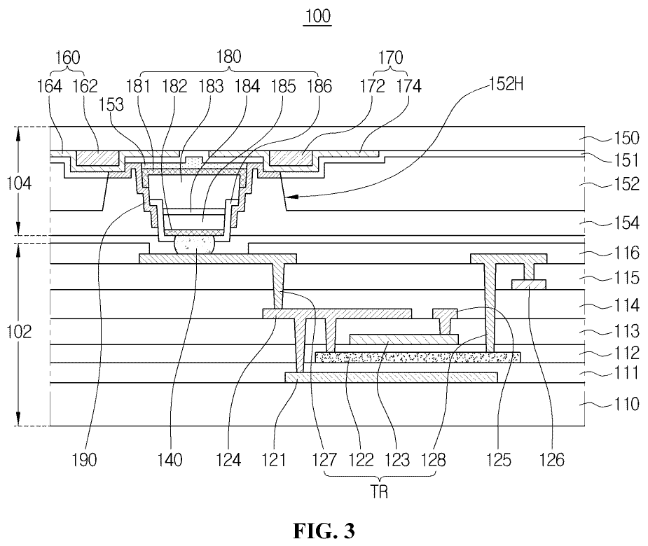

A cross sectional configuration of a display device according to an embodiment of the present disclosure will be described in detail with reference to FIG. 3.

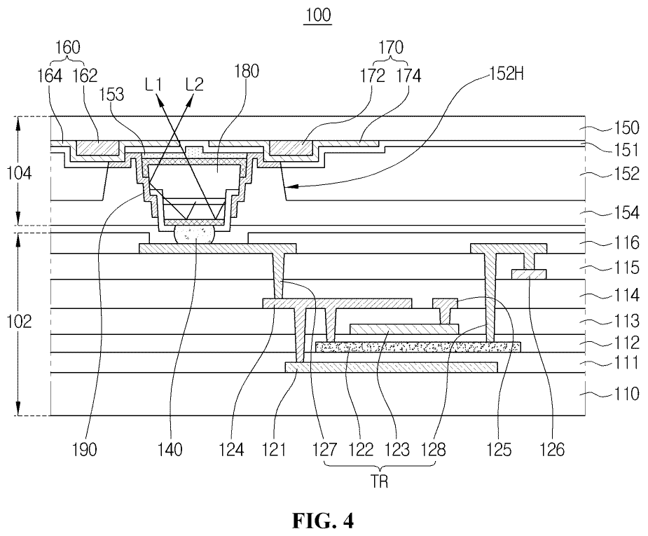

FIG. 3 is a schematic cross-sectional view of a display panel of a display device according to a first embodiment of the present disclosure, and FIG. 4 is a schematic view showing an optical path in the display panel of the display device according to the first embodiment of the present disclosure. The display device according to the first embodiment of the present disclosure can be a top emission type display device in which light from a light-emitting element is outputted to the outside through an upper substrate.

Referring to FIG. 3 and FIG. 4, the display device 100 according to the first embodiment of the present disclosure can include an array substrate 102 and an assembly substrate 104. The array substrate 102 can include a first substrate 110 on which a thin film transistor TR is provided, and the assembly substrate 104 can include a second substrate 150 on which first and second assembly lines 160 and 170 and a light-emitting element 180 are provided. The array substrate 102 and the assembly substrate 104 can be attached such that the thin film transistor TR and the light-emitting element 180 can be connected to each other. In this case, the thin film transistor TR and the light-emitting element 180 can be eutectic bonded by a bonding member 140.

Specifically, the first substrate 110 which is a lower substrate and the second substrate 150 which is an upper substrate can be spaced apart from each other. The first substrate 110 and the second substrate 150 can be a glass substrate or a plastic substrate. For example, polyimide can be used for the plastic substrate, and the plastic substrate can have a stacked structure including at least one polyimide layer and at least one inorganic layer. The first substrate 110 and the second substrate 150 can be formed of the same material.

However, embodiments of the present disclosure are not limited thereto. Alternatively, the first substrate 110 and the second substrate 150 can be formed of different materials. At this time, the first substrate 110 and the second substrate 150 can have different light transmittances. For example, the second substrate 150 can have a higher light transmittance than the first substrate 110. In this case, the second substrate 150 can be formed of a transparent material, and the first substrate 110 can be formed of an opaque material.

A light-shielding layer 121 can be provided on the first substrate 110, for example, on an inner surface of the first substrate 110. The light-shielding layer 121 can be formed of a conductive material such as metal. For example, the light-shielding layer 121 can be formed of one or more of: aluminum (Al), copper (Cu), molybdenum (Mo), titanium (Ti), chromium (Cr), nickel (Ni), tungsten (W), and an alloy thereof. The light-shielding layer 121 can have a single-layered structure or a multiple-layered structure.

A buffer layer 111 can be provided on the light-shielding layer 121. The buffer layer 111 can be disposed substantially all over the first substrate 110. The buffer layer 111 can be formed as a single layer or multiple layers of an inorganic insulating material. For example, the inorganic insulating material of the buffer layer 111 can include silicon nitride (SiNₓ), silicon oxide (SiOₓ), or silicon oxynitride (SiON).

An active layer 122 can be provided on the buffer layer 111. The active layer 122 can overlap the light-shielding layer 121, and the light-shielding layer 121 can block light incident on the active layer 122 and prevent the active layer 122 from deteriorating due to the light.

The active layer 122 can include a channel region at its central part and source and drain regions at both sides of the channel region. The active layer 122 can be formed of an oxide semiconductor material. Alternatively, the active layer 122 can be formed of polycrystalline silicon, and in this case, both ends of the active layer 122 can be doped with impurities.

A gate insulation layer 112 can be provided on the active layer 122 and the buffer layer 111. The gate insulation layer 112 can be disposed substantially all over the first substrate 110. The gate insulation layer 112 can be formed as a single layer or multiple layers of an inorganic insulating material. For example, the inorganic insulating material of the gate insulation layer 112 can include silicon nitride (SiNₓ), silicon oxide (SiOₓ), or silicon oxynitride (SiON).

A gate electrode 123 can be formed on the gate insulation layer 112. The gate electrode 123 can overlap the active layer 122 and can be disposed to correspond to the central part of the active layer 122. Accordingly, the gate electrode 123 can also overlap the light-shielding layer 121.

The gate electrode 123 can be formed of a conductive material such as metal. For example, the gate electrode 123 can be formed of one or more of: aluminum (Al), copper (Cu), molybdenum (Mo), titanium (Ti), chromium (Cr), nickel (Ni), tungsten (W), and an alloy thereof. The gate electrode 123 can have a single-layered structure or a multiple-layered structure.

A first interlayer insulation layer 113 can be provided on the gate electrode 123. The first interlayer insulation layer 113 can be disposed substantially all over the first substrate 110. The first interlayer insulation layer 113 can be formed as a single layer or multiple layers of an inorganic insulating material. For example, the inorganic insulating material of the first interlayer insulation layer 113 can include silicon nitride (SiNₓ), silicon oxide (SiOₓ), or silicon oxynitride (SiON).

A capacitor electrode 124 and an auxiliary electrode 125 can be provided on the first interlayer insulation layer 113. The capacitor electrode 124 can overlap the gate electrode 123 to thereby form a storage capacitor with the first interlayer insulation layer 113 therebetween as a dielectric.

In addition, the capacitor electrode 124 can also overlap the active layer 122 and the light-shielding layer 121. The capacitor electrode 124 can be in contact with the active layer 122 through a contact hole provided in the gate insulation layer 112 and the first interlayer insulation layer 113 and also be in contact with the light-shielding layer 121 through a contact hole provided in the buffer layer 111, the gate insulation layer 112, and the first interlayer insulation layer 113.

The auxiliary electrode 125 can overlap the gate electrode 123 and can be in contact with the gate electrode 123 through a contact hole provided in the first interlayer insulation layer 113.

The capacitor electrode 124 and the auxiliary electrode 125 can be formed of a conductive material such as metal. For example, the capacitor electrode 124 and the auxiliary electrode 125 can be formed of one or more of: aluminum (Al), copper (Cu), molybdenum (Mo), titanium (Ti), chromium (Cr), nickel (Ni), tungsten (W), and an alloy thereof. The capacitor electrode 124 and the auxiliary electrode 125 can have a single-layered structure or a multiple-layered structure.

A second interlayer insulation layer 114 can be provided on the capacitor electrode 124 and the auxiliary electrode 125. The second interlayer insulation layer 114 can be disposed substantially all over the first substrate 110. The second interlayer insulation layer 114 can be formed as a single layer or multiple layers of an inorganic insulating material. For example, the inorganic insulating material of the second interlayer insulation layer 114 can include silicon nitride (SiNₓ), silicon oxide (SiOₓ), or silicon oxynitride (SiON).

A first power line 126 can be provided on the second interlayer insulation layer 114. The first power line 126 can be spaced apart from the gate electrode 123, the capacitor electrode 124, and the auxiliary electrode 125. For example, the first power line 126 can transmit a high potential voltage VDD.

The first power line 126 can be formed of a conductive material such as metal. For example, the first power line 126 can be formed of one or more of: aluminum (Al), copper (Cu), molybdenum (Mo), titanium (Ti), chromium (Cr), nickel (Ni), tungsten (W), and an alloy thereof. The first power line 126 can have a single-layered structure or a multiple-layered structure.

A first passivation layer 115 can be provided on the first power line 126. The first passivation layer 115 can be disposed substantially all over the first substrate 110. The first passivation layer 115 can be formed as a single layer or multiple layers of an inorganic insulating material. For example, the inorganic insulating material of the first passivation layer 115 can include silicon nitride (SiNₓ), silicon oxide (SiOₓ), or silicon oxynitride (SiON). The first passivation layer 115 can be omitted.

A source electrode 127 and a drain electrode 128 can be provided on the first passivation layer 115. The source electrode 127 and the drain electrode 128 can be spaced apart from each other with the gate electrode 123 positioned therebetween and can be electrically connected to both ends of the active layer 122, respectively.

The source electrode 127 can overlap the capacitor electrode 124 and can be in contact with the capacitor electrode 124 through a contact hole provided in the second interlayer insulation layer 114 and the first passivation layer 115. Accordingly, the source electrode 127 can be electrically connected to the active layer 122 through the capacitor electrode 124.

The drain electrode 128 can overlap the active layer 122 and can be in direct contact with the active layer 122 through a contact hole provided in the first interlayer insulation layer 113, the second interlayer insulation layer 114, and the first passivation layer 115.

However, embodiments of the present disclosure are not limited thereto. In other embodiments, the source electrode 127 can be in direct contact with the active layer 122, and the drain electrode 128 can be electrically connected to the active layer 122 through another element. The locations of the source electrode 127 and the drain electrode 128 can be changed.

In addition, the drain electrode 128 can also overlap the first power line 126 and can be in contact with the first power line 126 through a contact hole provided in the first passivation layer 115.

The source electrode 127 and the drain electrode 128 can be formed of a conductive material such as metal. For example, the source electrode 127 and the drain electrode 128 can be formed of one or more of: aluminum (Al), copper (Cu), molybdenum (Mo), titanium (Ti), chromium (Cr), nickel (Ni), tungsten (W), and an alloy thereof. The source electrode 127 and the drain electrode 128 can have a single-layered structure or a multiple-layered structure.

Meanwhile, the source electrode 127 can extend and overlap the light-emitting element 180. The source electrode 127 can function as a reflection electrode. In this case, the source electrode 127 and the drain electrode 128 can be formed of a material having relatively high reflectance.

The active layer 122, the gate electrode 123, the source electrode 127, and the drain electrode 128 can constitute the thin film transistor TR. The thin film transistor TR can be the driving transistor DT of FIG. 2.

A second passivation layer 116 can be provided on the source electrode 127 and the drain electrode 128. The second passivation layer 116 can expose a portion of the source electrode 127 and can be disposed substantially all over the first substrate 110.

The second passivation layer 116 can be formed as a single layer or multiple layers of an inorganic insulating material. The inorganic insulating material of the second passivation layer 116 can include silicon nitride (SiNₓ), silicon oxide (SiOₓ), or silicon oxynitride (SiON). However, embodiments of the present disclosure are not limited thereto. In other embodiments, the second passivation layer 116 can be configured as a planarization layer that is formed of an organic insulating material.

Next, a first lower line 162 and a second lower line 172 can be provided under the second substrate 150, for example, on an inner surface of the second substrate 150. The first lower line 162 and the second lower line 172 can be spaced apart from each other. The first lower line 162 and the second lower line 172 can be formed of a conductive material such as metal. For example, the first lower line 162 and the second lower line 172 can be formed of copper (Cu) or chromium (Cr).

A first upper line 164 and a second upper line 174 can be provided under the first lower line 162 and the second lower line 172, respectively. The first upper line 164 and the second upper line 174 can be spaced apart from each other. The first upper line 164 and the second upper line 174 can overlap and be in contact with the first lower line 162 and the second lower line 172, respectively.

The first lower line 162 and the first upper line 164 can constitute the first assembly line 160, and the second lower line 172 and the second upper line 174 can constitute the second assembly line 170.

The first upper line 164 can cover top and side surfaces of the first lower line 162 and can be in electrical contact with the first lower line 162. The second upper line 174 can cover top and side surfaces of the second lower line 172 and can be in electrical contact with the second lower line 172. The first upper line 164 and the second upper line 174 can have wider widths than the first lower line 162 and the second lower line 172, respectively, and can be in contact with the inner surface of the second substrate 150.

The first upper line 164 and the second upper line 174 can be formed of a conductive material such as metal. The first upper line 164 and the second upper line 174 can be formed of a material that is more resistant to corrosion than the first lower line 162 and the second lower line 172, so that a short-circuiting defect caused by migration of the materials of the first lower line 162 and the second lower line 172 can be minimized during manufacturing the display device 100.

For example, the first upper line 164 and the second upper line 174 can be formed of molybdenum (Mo) or molybdenum titanium (MoTi), but embodiments of the present disclosure are not limited thereto.

A first insulation layer 151 can be provided under the first upper line 164 and the second upper line 174. The first insulation layer 151 can cover the first assembly line 160 and the second assembly line 170 and can be disposed substantially all over the second substrate 150. The first insulation layer 151 can be in contact with the inner surface of the second substrate 105 and can expose portions of the first assembly line 160 and the second assembly line 170, i.e., portions of the first upper line 164 and the second upper line 174.

The first insulation layer 151 can be formed of an inorganic insulating material. For example, the inorganic insulating material of the first insulation layer 151 can include silicon nitride (SiNₓ), silicon oxide (SiOₓ), or silicon oxynitride (SiON).

A second insulation layer 152 can be provided as a first planarization layer under the first insulation layer 151. The second insulation layer 152 can have an assembly hole 152H corresponding to the first assembly line 160 and the second assembly line 170 and can partially cover the first assembly line 160 and the second assembly line 170. The assembly hole 152H can be disposed to correspond to the exposed portion of the source electrode 127.

The second insulation layer 152 can be formed of an organic insulating material such as photosensitive acrylic polymer (photo acryl), for example.

Then, an adhesive layer 153 and the light-emitting element 180 can be provided in the assembly hole 152H of the second insulation layer 152. The adhesive layer 153 and the light-emitting element 180 can overlap the source electrode 127.

The adhesive layer 153 can be disposed between the first insulation layer 151 and the light-emitting element 180. The adhesive layer 153 can be formed of a photocurable adhesive material that is cured by light. For example, the adhesive layer 153 can be formed of photosensitive acrylic polymer (photo acryl). However, embodiments of the present disclosure are not limited thereto. Alternatively, the adhesive layer 153 can be formed of one of a polyimide (PI) resin, an epoxy resin, a urethane resin, and a polydimethylsiloxane (PDMS) resin.

The light-emitting element 180 can be provided in the form of a micro light-emitting diode chip (micro LED chip or uLED chip) including an n-electrode, an n-type layer, an active layer, a p-type layer, and a p-electrode. The light-emitting element 180 can have a vertical structure in which the n-electrode and the p-electrode are provided on opposite sides, respectively.

However, embodiments of the present disclosure are not limited thereto. In other embodiments, the light-emitting element 180 can have a lateral structure in which the n-electrode and the p-electrode are provided on the same side and light is emitted through the side provided with the n-electrode and the p-electrode or a flip-chip structure in which the n-electrode and the p-electrode are provided on the same side and light is emitted through another side opposite to the side provided with the n-electrode and the p-electrode.

The light-emitting element 180 can include a first element electrode 181, a second element electrode 182, a first semiconductor layer 183, a light-emitting layer 184, a second semiconductor layer 185, and a protection layer 186.

The first element electrode 181 can be provided on a side of the light-emitting element 180 facing the second substrate 150, and the second element electrode 182 can be provided on a side of the light-emitting element 180 facing the first substrate 110. Here, the first element electrode 181 can be an n-electrode, and the second element electrode 182 can be a p-electrode. The first element electrode 181 can be a cathode, and the second element electrode 182 can be an anode.

However, embodiments of the present disclosure are not limited thereto. Alternatively, in other embodiments, the first element electrode 181 can be a p-electrode, and the second element electrode 182 can be an n-electrode. In this case, the first element electrode 181 can be an anode, and the second element electrode 182 can be a cathode.

The first element electrode 181 and the second element electrode 182 can be formed of a conductive material. For example, the first element electrode 181 and the second element electrode 182 can be formed of a transparent conductive material such as indium tin oxide (ITO) or indium zinc oxide (IZO) or an opaque conductive material such as titanium (Ti), gold (Au), silver (Ag), copper (Cu), or an alloy thereof. However, embodiments of the present disclosure are not limited thereto.

The first element electrode 181 and the second element electrode 182 can be formed of the same material. In this case, the first element electrode 181 and the second element electrode 182 can be formed of a transparent conductive material or a semi-transparent conductive material.

Alternatively, the first element electrode 181 and the second element electrode 182 can be formed of different materials. In this case, one of the first element electrode 181 and the second element electrode 182 can be formed of a transparent conductive material, and the other can be formed of a semi-transparent conductive material or an opaque conductive material. For example, the first element electrode 181 can be formed of a transparent conductive material, and the second element electrode 182 can be formed of a semi-transparent conductive material or an opaque conductive material. Accordingly, the first element electrode 181 can have higher light transmittance than the second element electrode 182.

The first semiconductor layer 183, the light-emitting layer 184, and the second semiconductor layer 185 can be provided between the first element electrode 181 and the second element electrode 182, and the light-emitting layer 184 can be disposed between the first semiconductor layer 183 and the second semiconductor layer 185.

The first semiconductor layer 183 and the second semiconductor layer 185 can be formed by doping n-type or p-type impurities into a semiconductor material. For example, the first semiconductor layer 183 and the second semiconductor layer 185 can be formed by doping n-type or p-type impurities into gallium nitride (GaN), indium aluminum phosphide (InAlP), or gallium arsenide (GaAs). In addition, for example, the n-type impurities can be silicon (Si), germanium (Ge), or tin (Sn), and the p-type impurities can be magnesium (Mg), zinc (Zn), or beryllium (Be). However, embodiments of the present disclosure are not limited thereto.

The first semiconductor layer 183 can have a larger area than the second semiconductor layer 185. At least a part of the first semiconductor layer 183 can protrude outside the second semiconductor layer 185.

The light-emitting layer 184 can receive electrons and holes from the first semiconductor layer 183 and the second semiconductor layer 185, respectively, and emit light. The light-emitting layer 184 can be formed of a single quantum well (SQW) structure or a multi quantum well (MQW) structure. For example, the light-emitting layer 184 can be formed of indium gallium nitride (InGaN) or gallium nitride (GaN), but is not limited thereto.

The protection layer 186 can cover and protect top and side surfaces of the second element electrode 182 and can partially expose the top surface of the second element electrode 182. In addition, the protection layer 186 can cover and protect side surfaces of the first semiconductor layer 183, the light-emitting layer 184, and the second semiconductor layer 185.

The protection layer 186 can be spaced apart from the first element electrode 181. However, embodiments of the present disclosure are not limited thereto. In other embodiments, the protection layer 186 can partially overlap the first element electrode 181.

The protection layer 186 can be formed as a single layer or multiple layers of an inorganic insulating material. The inorganic insulating material of the protection layer 186 can include silicon nitride (SiNₓ), silicon oxide (SiOₓ), or silicon oxynitride (SiON).

Further, a connection electrode 190 can be provided in the assembly hole 152H of the second insulation layer 152. In this case, the connection electrode 190 can be disposed between the light-emitting element 180 and the second insulation layer 152.

The connection electrode 190 can be in contact with the first element electrode 181 and also be in contact with the first assembly line 160 and the second assembly line 170. Specifically, the connection electrode 190 can be in contact with the first upper line 164 and the second upper line 174 exposed through contact holes of the first insulation layer 151.

Accordingly, the first element electrode 181 can be electrically connected to the first and second assembly lines 160 and 170 through the connection electrode 190.

In addition, the connection electrode 190 can be provided along a side surface of the light-emitting element 180 and can be in contact with the protection layer 186. In this case, the connection electrode 190 can be provided to correspond to side surfaces of the first semiconductor layer 183, the light-emitting layer 184, and the second semiconductor layer 186 and can cover and overlap the side surface of the light-emitting layer 184.

The connection electrode 190 can be formed of a metal material having relatively high reflectance. Accordingly, the connection electrode 190 can reflect light emitted from the light-emitting layer 184 and directed toward the side surface of the light-emitting element 180. For example, the connection electrode 190 can be formed of aluminum (Al), silver (Ag), or chromium (Cr).

A third insulation layer 154 can be provided as a second planarization layer under the second substrate 150 provided with the connection electrode 190. The third insulation layer 154 can also be disposed under the second insulation layer 152. The third insulation layer 154 can cover and protect the side surface of the light-emitting element 180. In addition, the third insulation layer 154 can cover the connection electrode 190 and the second insulation layer 152.

The third insulation layer 154 can be formed of an organic insulating material such as photosensitive acrylic polymer (photo acryl), for example.

The third insulation layer 154 can expose a top surface of the light-emitting element 180. Accordingly, the third insulation layer 154 can expose the second element electrode 182 that is exposed by the protection layer 186.

A bonding member 140 can be provided between the exposed second element electrode 182 and the source electrode 127. The bonding member 140 can be in contact with the second element electrode 182 and the source electrode 127. In this case, the second element electrode 182 and the source electrode 127 can be eutectic bonded by the bonding member 140 and be electrically connected to each other. For example, the light-emitting element 180 can be electrically connected to the thin film transistor TR through the bonding member 140.

Accordingly, the light-emitting element 180, i.e., the second element electrode 182 of the light-emitting element 180 can be electrically connected to the first power line 126 through the thin film transistor TR.

The bonding member 140 can be provided in the form of a bump. The bonding member 140 can be formed of gold/germanium (Au/Ge) or gold/indium (Au/In), but embodiments of the present disclosure are not limited thereto.

Referring to FIG. 4, in the display device according to the first embodiment of the present disclosure, the first light L1 emitted from the light-emitting layer 184 and directed toward the side surface of the light-emitting element 180 can be reflected by the second element electrode 182, which acts as a reflection electrode, to thereby be directed toward the second substrate 150, and can be output to the outside through the second substrate 150 after passing through the first element electrode 181. In this case, some of the first light L1 can pass through the second element electrode 182 and can be directed toward the first substrate 110. However, the some of the first light L1 can be reflected by the source electrode 127, which has a relatively high reflectance and acts as another reflection electrode, and can be directed toward the second substrate 150. After passing through the first element electrode 181, the some of the first light L1 can be output to the outside through the second substrate 150.

Next, second light L2 emitted from the light-emitting layer 184 and directed toward the first substrate 110 can be reflected by the second element electrode 182, which acts as a reflection electrode, to thereby be directed toward the side surface of the light-emitting element 180, can be reflected by the connection electrode 190 provided on the side surface of light-emitting element 180 to thereby be directed toward the second substrate 150, and can be output to the outside through the second substrate 150 after passing through the first element electrode 181.

As such, in the display device according to the first embodiment of the present disclosure, the light-emitting element 180 can be self-assembled on the second substrate 150 of the assembly substrate 104, and the array substrate 102 provided with the thin film transistor TR and the assembly substrate 104 provided with the light-emitting element 180 can be attached to each other, so that the step of transferring the light-emitting element 180 can be decreased. This will be described in detail later.

In addition, by using the first and second assembly lines 160 and 170 of the assembly substrate 104 as a power line, it is possible to sufficiently cope with a relatively high power voltage required for high resolution.

More particularly, as the resolution increases, a higher power voltage can be required, and in order to stably supply the power voltage, a power line with a wider area can be required. Since a plurality of lines and a plurality of electrodes are provided on the array substrate 102, there can be a limitation in increasing the area of the power line on the array substrate 102.

However, in the display device according to the first embodiment of the present disclosure, by using the first and second assembly lines 160 and 170 of the assembly substrate 104 provided separately from the array substrate 102 as the power line, it is possible to increase the area of the power line substantially without restrictions, and it is possible to stably supply the relatively high power voltage required for high resolution.

In addition, the light-emitting element 180 and the first and second assembly lines 160 and 170 can be connected by the connection electrode 190, and light directed toward the side surface of the light-emitting element 180 can be reflected by the connection electrode 190 and be output to the outside, thereby improving the light extraction efficiency of the light-emitting element 180.

Meanwhile, in the display device according to the first embodiment of the present disclosure, the light-emitting element 180 can be spaced apart from the active layer 120. However, in other embodiments, the light-emitting element 180 can overlap at least a portion of the active layer 122.

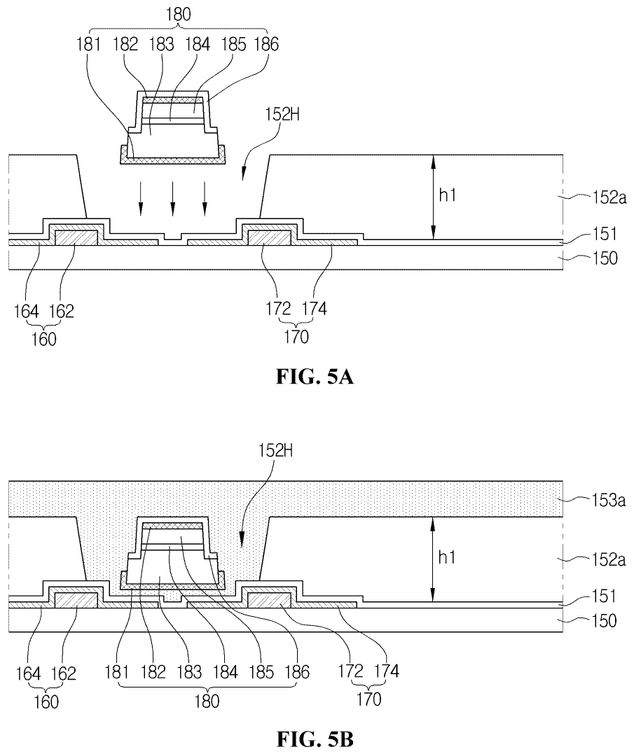

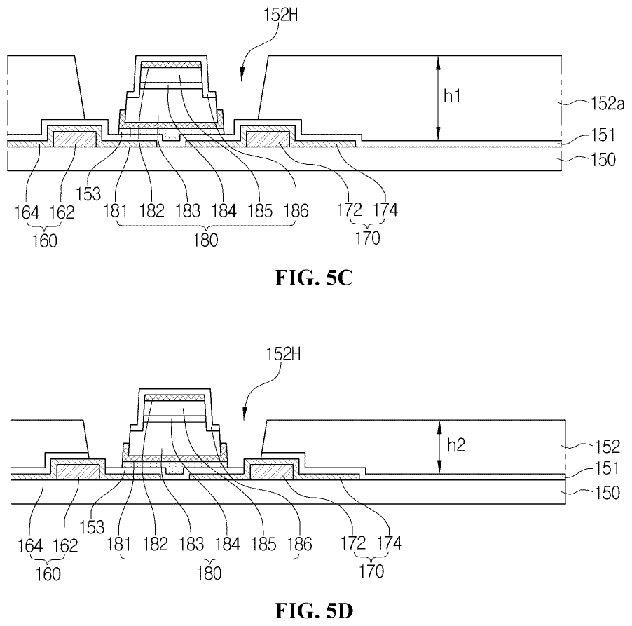

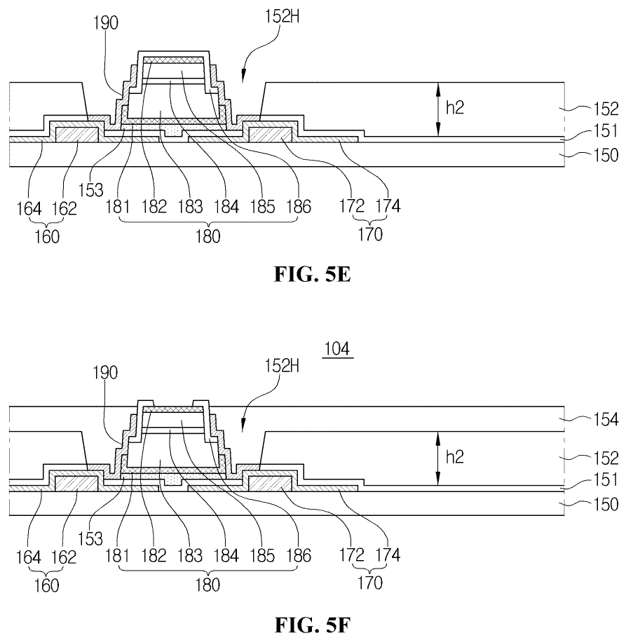

A method of manufacturing a display device according to the first embodiment of the present disclosure will be described with reference to FIGS. 5A to 5F.

FIGS. 5A to 5F are schematic cross-sectional views of an assembly substrate of a display device for explaining the steps of manufacturing the display device according to the first embodiment of the present disclosure.

Referring to FIG. 5A, the first and second lower lines 162 and 172 can be formed on the second substrate 150 by depositing a conductive material and patterning it through a photolithography process, and the first and second upper lines 164 and 174 can be formed on the first and second lower lines 162 and 172 by depositing a conductive material and patterning it through a photolithography process, thereby completing the first and second assembly lines 160 and 170.

Then, the first insulation layer 151 can be formed on the first and second assembly lines 160 and 170 by depositing an inorganic insulating material, and a second insulation layer 152a having the assembly hole 152H can be formed on the first insulation layer 151 by applying an organic insulating material and patterning it through a photolithography process. Here, the second insulation layer 152a can have a first height h1.

Next, the light-emitting element 180 can be self-assembled in the assembly hole 152H. In this case, the second substrate 150 provided with the second insulation layer 152 including the assembly hole 152H can be disposed over a chamber provided with a fluid in which a plurality of light-emitting elements 180 are dispersed. A magnetic field can be generated over the second substrate 150 to move the light-emitting elements 180 toward the second substrate 150. When an AC voltage is applied to the first and second assembly lines 160 and 170, an electric field can be generated between the first and second assembly lines 160 and 170, and the light-emitting element 180 can be self-assembled in the assembly hole 152H by a dielectric phoretic force caused by the generated electric field.

Here, the protection layer 186 of the light-emitting element 180 can cover the second element electrode 182 without exposing it.

Next, referring to FIG. 5B, an adhesive material layer 153a can be formed on the light-emitting element 180 self-assembled in the assembly hole 152H and the second insulation layer 152a. In this case, the light-emitting element 180 can be spaced apart from the first insulation layer 152 on the first and second assembly lines 160 and 170, and the adhesive material layer 153a can also be disposed between the light-emitting element 180 and the first insulation layer 151. For example, the light-emitting element 180 can be enclosed by the adhesive material layer 153a.

Next, referring to FIG. 5C, the adhesive layer 153 can be formed under the light-emitting element 180 by patterning the adhesive material layer 153a through a photolithography process and heat-treating it. The adhesive layer 153 can be disposed between the light-emitting element 180 and the first insulation layer 151 and can attach and fix the light-emitting element 180 to the first insulation layer 151. The adhesive layer 153 can be spaced apart from the second insulation layer 152a.

Next, referring to FIG. 5D, the second insulation layer 152a having the first height h1 can be partially removed from its top surface through an ashing process, thereby forming the second insulation layer 152 having a second height h2. Here, the second height h2 of the second insulation layer 152 can be lower than the height of the light-emitting element 180.

Then, the first insulation layer 151 in the assembly hole 152H can be selectively removed through a dry etching process, thereby partially exposing the first assembly line 160 and the second assembly line 170. In this case, the first upper line 164 and the second upper line 174 can be exposed.

Next, referring to FIG. 5E, the connection electrode 190 can be formed by depositing a conductive material and patterning it through a photolithography process. The connection electrode 190 can be in connect with the first element electrode 181 and also be in contact with the exposed first and second upper lines 164 and 174. Accordingly, the first element electrode 181 can be electrically connected to the first and second assembly lines 160 and 170 through the connection electrode 190.

In addition, the connection electrode 190 can be provided to correspond to the side surfaces of the first semiconductor layer 183, the light-emitting layer 184, and the second semiconductor layer 185 and can cover and overlap the side surface of the light-emitting layer 184. The connection electrode 190 can also be in contact with the protection layer 186.

Next, referring to FIG. 5F, the third insulation layer 154 can be formed by applying an organic insulating material and can be partially removed through an ashing process to thereby expose the protection layer 186 of the light-emitting element 180. Then, the protection layer 186 can be partially removed through a dry etching process, thereby partially exposing the second element electrode 182.

Accordingly, the assembly substrate 104 can be completed in which the light-emitting element 180 can be self-assembled on the first and second assembly lines 160 and 170 and can be electrically connected to the first and second assembly lines 160 and 170.

Then, the assembly substrate 104 can be attached to the array substrate 102 of FIG. 3, thereby manufacturing the display device according to the first embodiment of the present disclosure.

As such, in the method of manufacturing the display device according to the first embodiment of the present disclosure, after self-assembling the light-emitting element 180 on the assembly substrate 104, the first element electrode 181 of the light-emitting element 180 can be connected to the first and second assembly lines 160 and 170, and the assembly substrate 104 provided with the light-emitting element 180 can be attached to the array substrate 102 of FIG. 3.

Accordingly, by transferring the light-emitting element 180 without using a stamp, the transfer steps of the light-emitting element 180 can be reduced, defects due to complex transfer steps can be decreased, and the manufacturing time and costs can be reduced.

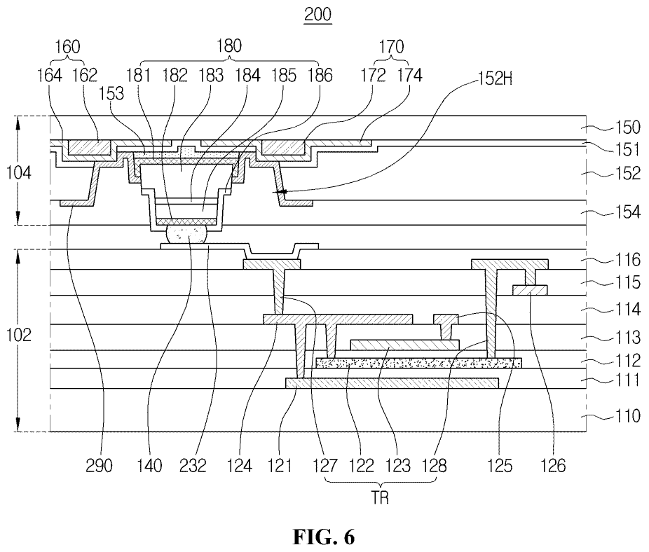

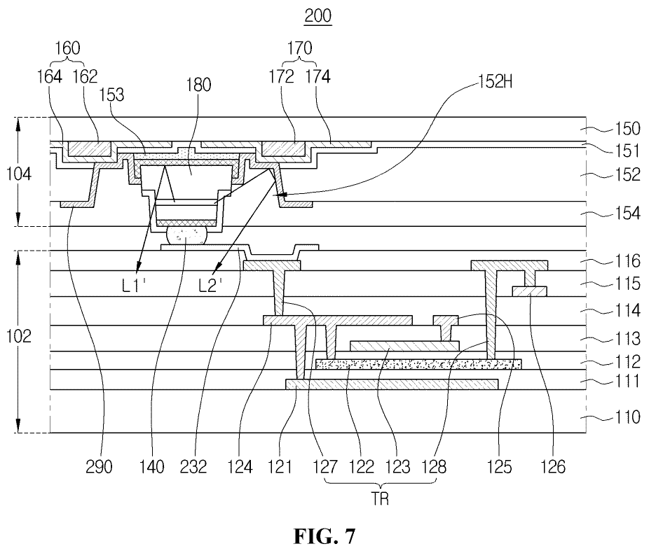

Meanwhile, embodiments of the present disclosure can be applied to a bottom emission type display device. A display device according to a second embodiment of the present disclosure will be described with reference to FIG. 6 and FIG. 7.

FIG. 6 is a schematic cross-sectional view of a display panel of a display device according to the second embodiment of the present disclosure, and FIG. 7 is a schematic view showing an optical path in the display panel of the display device according to the second embodiment of the present disclosure. The display device according to the second embodiment of the present disclosure can be a bottom emission type display device in which light from a light-emitting element is outputted to the outside through a lower substrate.

The display device according to the second embodiment of the present disclosure has substantially the same or similar configuration as that of the first embodiment, except for the connection electrode and the contact electrode. The same parts as those of the first embodiment are designated by the same or similar reference signs, and explanation for the same parts can be shortened or omitted.

Referring to FIG. 6 and FIG. 7, a display device 200 according to the second embodiment of the present disclosure can include the array substrate 102 and the assembly substrate 104.

The thin film transistor TR can be provided on the first substrate 110 of the array substrate 102, the second passivation layer 116 can be provided on the thin film transistor TR, and a contact electrode 232 can be provided on the second passivation layer 116. The contact electrode 232 can be in contact with the source electrode 127 of the thin film transistor TR through a contact hole formed in the second passivation layer 116.

The contact electrode 232 can be formed of a transparent conductive material. For example, the contact electrode 232 can be formed of indium tin oxide (ITO) or indium zinc oxide (IZO), but embodiments of the present disclosure are not limited thereto.

The first and second assembly lines 160 and 170 can be provided under the second substrate 150 of the assembly substrate 104, the first and second insulation layers 151 and 152 can be provided under the first and second assembly lines 160 and 170, and the adhesive layer 153 and the light-emitting element 180 can be provided in the assembly hole 152H of the second insulation layer 152.

Here, the first element electrode 181 and the second element electrode 182 of the light-emitting element 180 can be formed of the same material or formed of different materials. When the first element electrode 181 and the second element electrode 182 of the light-emitting element 180 are formed of different materials, the second element electrode 182 can have higher light transmittance than the first element electrode 181. In this case, the first element electrode 181 can be formed of a semi-transparent conductive material or an opaque conductive material, and the second element electrode 182 can be formed of a transparent conductive material.

In addition, a connection electrode 290 can be provided in the assembly hole 152H. In this case, the connection electrode 290 can be disposed substantially between the light-emitting element 180 and the second insulation layer 152 and can cover the side and top surfaces of the second insulation layer 152 corresponding to the assembly hole 152H.

The connection electrode 290 can be provided along the side surface of the light-emitting element 180. The connection electrode 290 can be in contact with the first element electrode 181 and also be in contact with the first upper line 164 and the second upper line 174 exposed through the contact hole of the first insulation layer 151. Accordingly, the first element electrode 181 can be electrically connected to the first and second assembly lines 160 and 170 through the connection electrode 290.

The connection electrode 290 can be provided to correspond to the side surface of the first semiconductor layer 183 and can be in contact with the side surface of the first semiconductor layer 183. Alternatively, the connection electrode 290 can be spaced apart from the side surface of the first semiconductor layer 183.

In addition, the connection electrode 290 can be spaced apart from the light-emitting layer 184 and the second semiconductor layer 185 and can also be spaced apart from the protection layer 186.

The connection electrode 290 can be formed of a metal material having relatively high reflectance so as to serve as a reflection electrode. Accordingly, the connection electrode 290 can reflect light emitted from the light-emitting layer 184 and directed toward the side surface of the light-emitting element 180. For example, the connection electrode 290 can be formed of aluminum (Al), silver (Ag), or chromium (Cr).

The third insulation layer 154 can be provided under the second substrate 150 provided with the connection electrode 290. The third insulation layer 154 can cover and protect the side surfaces of the light-emitting element 180, the connection electrode 290, and the second insulation layer 152.

The bonding member 140 can be provided between the second element electrode 182 and the contact electrode 232 of the array substrate 102. The bonding member 140 can be in contact with the second element electrode 182 and the contact electrode 232. In this case, the second element electrode 182 and the contact electrode 232 can be eutectic bonded by the bonding member 140 and be electrically connected to each other. For example, the light-emitting element 180 can be electrically connected to the thin film transistor TR through the bonding member 140 and the contact electrode 232.

Referring to FIG. 7, in the display device according to the second embodiment of the present disclosure, the first light L1′ emitted from the light-emitting layer 184 and directed toward the second substrate 150 can be reflected by the first element electrode 181, which acts as another reflection electrode, to thereby be directed toward the first substrate 110, and can be output to the outside through the first substrate 110. Here, the first light L1′ can be output to the outside through the first substrate 110 after passing through the second element electrode 182 and/or the contact electrode 232.

Next, the second light L2′ emitted from the light-emitting layer 184 and directed toward the side surface of the light-emitting element 180 can be reflected by the connection electrode 290 to thereby be directed toward the first substrate 110, and can be output to the outside through the first substrate 110 after passing through the contact electrode 232. Here, the second light L2′ can be reflected by the connection electrode 290 and then can be output to the outside through the first substrate 110 without passing through the contact electrode 232.

As such, in the display device according to the second embodiment of the present disclosure, light from the light-emitting element 180 can be output to the outside through the first substrate 110, which is a lower substrate.

In addition, by attaching the assembly substrate 104 provided with the self-assembled light-emitting element 180 and the array substrate 102 provided with the thin film transistor TR, the transfer steps of the light-emitting element 180 can be reduced.

Further, by using the first and second assembly lines 160 and 170 of the assembly substrate 104 as a power line, it is possible to sufficiently cope with a relatively high power voltage required for high resolution.

Moreover, the light-emitting element 180 and the first and second assembly lines 160 and 170 can be connected by the connection electrode 290, and light directed toward the side surface of the light-emitting element 180 can be reflected by the connection electrode 290 and be output to the outside, thereby improving the light extraction efficiency of the light-emitting element 180.

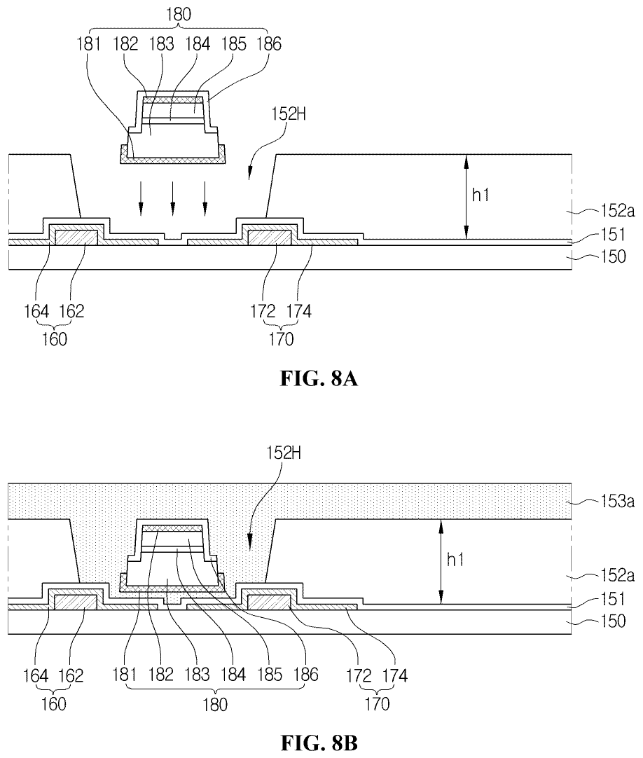

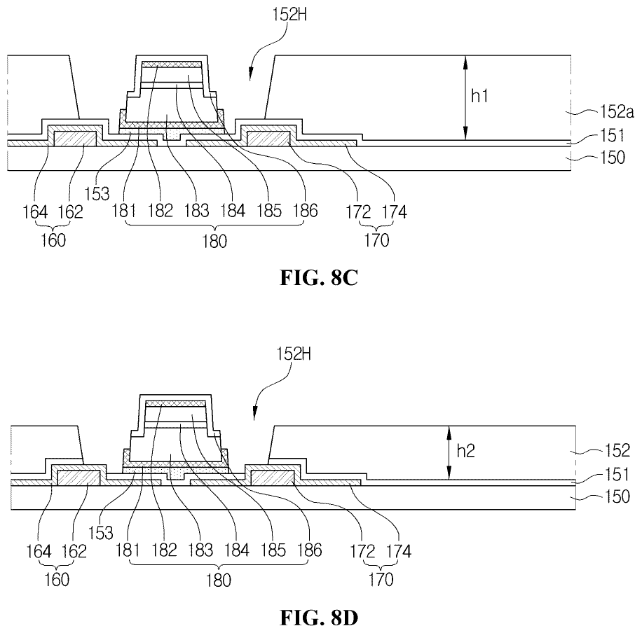

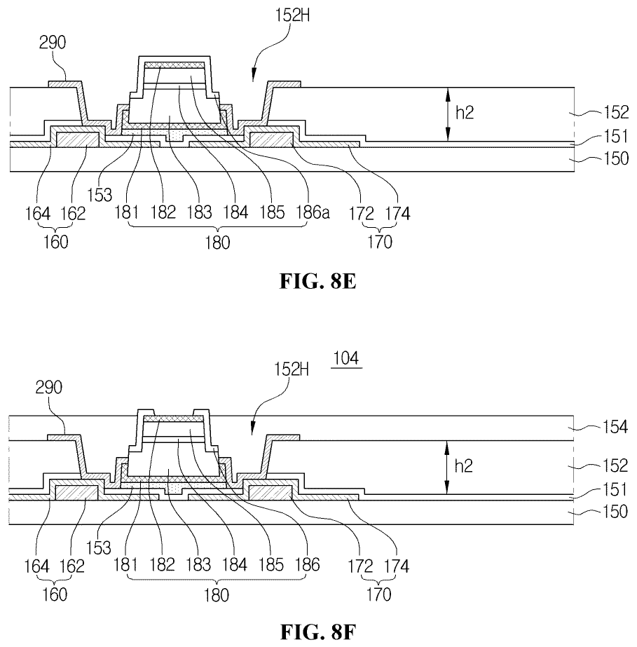

A method of manufacturing a display device according to the second embodiment of the present disclosure will be described with reference to FIGS. 8A to 8F.

FIGS. 8A to 8F are schematic cross-sectional views of an assembly substrate of a display device for explaining the steps of manufacturing the display device according to the second embodiment of the present disclosure.

The method of manufacturing the display device according to the second embodiment of the present disclosure has substantially the same or similar configuration as that of the first embodiment, except for steps of forming the connection electrode and the contact electrode. The same parts as those of the first embodiment are designated by the same or similar reference signs, and explanation for the same parts can be shortened or omitted.

Referring to FIG. 8A, the second substrate 150 provided with the first and second assembly electrodes 160 and 170, the first insulation layer 151, and the second insulation layer 152a of the first height h1 can be prepared, and the light-emitting element 180 can be self-assembled in the assembly hole 152H of the second insulation layer 152a.

Next, referring to FIG. 8B, the adhesive material layer 153a can be formed on the self-assembled light-emitting element 180 and the second insulation layer 152a. In this case, the adhesive material layer 153a can also be disposed between the light-emitting element 180 and the first insulation layer 151.

Next, referring to FIG. 8C, the adhesive layer 153 can be formed under the light-emitting element 180 by patterning the adhesive material layer 153a through a photolithography process and heat-treating it.

Next, referring to FIG. 8D, the second insulation layer 152 having the second height h2 can be formed through an ashing process, and the first insulation layer 151 in the assembly hole 152H can be selectively removed through a dry etching process, thereby partially exposing the first upper line 164 and the second upper line 174.

Next, referring to FIG. 8E, the connection electrode 290 can be formed by depositing a conductive material and patterning it through a photolithography process. The connection electrode 290 can be in contact with and electrically connected to the first element electrode 181 and the first and second assembly lines 160 and 170.

The connection electrode 290 can be provided to correspond to the side surface of the first semiconductor layer 183 and can cover the side and top surfaces of the second insulation layer 152 corresponding to the assembly hole 152H. In addition, connection electrode 290 may not overlap the light-emitting layer 184 and the second semiconductor layer 185 and can be spaced apart from the protection layer 186.

Next, referring to FIG. 8F, the third insulation layer 154 exposing the protection layer 186 of the light-emitting element 180 can be formed, and the protection layer 186 can be partially removed through a dry etching process, thereby partially exposing the second element electrode 182.

Accordingly, the assembly substrate 104 can be completed, and can be attached to the array substrate 102 of FIG. 6 on which the contact electrode 232 is formed, thereby manufacturing the display device according to the second embodiment of the present disclosure.

As such, in the method of manufacturing the display device according to the second embodiment of the present disclosure, by transferring the light-emitting element 180 without using a stamp, the transfer steps of the light-emitting element 180 can be reduced, defects due to complex transfer steps can be decreased, and the manufacturing time and costs can be reduced.

In the display devices according to the first and second embodiments of the present disclosure, the first and second assembly lines 160 and 170 can be spaced apart from each other in the first direction X and can extend in the second direction Y, and the light-emitting elements 180 can be arranged in the second direction Y.

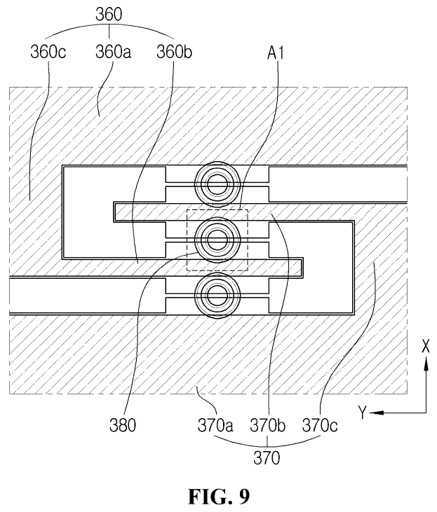

However, embodiments of the present disclosure are not limited thereto, and the arrangement of the first and second assembly lines and the light-emitting element can vary. Display devices according to third and fourth embodiments of the present disclosure will be described with reference to FIGS. 9 to 12.

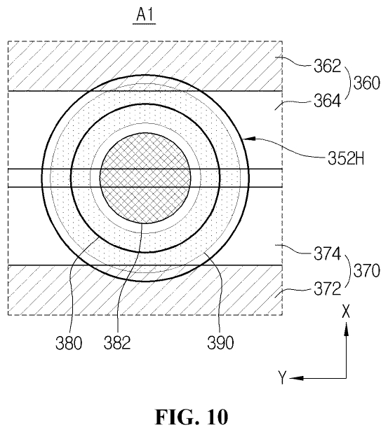

FIG. 9 is a schematic plan view of a display device according to a third embodiment of the present disclosure, and FIG. 10 is a schematic plan view enlarging area A1 of FIG. 9. The display device according to the third embodiment of the present disclosure can be a top emission type display device and can have substantially the same cross-sectional configuration as that of FIG. 3.

Referring to FIG. 9 and FIG. 10, each of the first and second assembly lines 360 and 370 can have substantially a U-like shape. Portions of the first and second assembly lines 360 and 370 can be alternately arranged along the first direction X, and the light-emitting elements 380 can be arranged in the first direction X.

Specifically, the first assembly line 360 can include first, second, and third portions 360a, 360b, and 360c, and the second assembly line 370 can include fourth, fifth, and sixth portions 370a, 370b, and 370c. The first and second portions 360a and 360b of the first assembly line 360 can extend in the second direction Y. The third portion 360c can extend in the first direction X and can connect the first and second portions 360a and 360b. The fourth and fifth portions 370a and 370b of the second assembly line 370 can extend in the second direction Y. The sixth portion 370c can extend in the first direction X and can connect the fourth and fifth portions 370a and 370b.

The fifth portion 370b of the second assembly line 370 can be disposed between the first and second portions 360a and 360b of the first assembly line 360. The second portion 360b of the first assembly line 360 can be disposed between the fourth and fifth portions 370a and 370b of the second assembly line 370.

The first assembly line 360 can include a first lower line 362 and a first upper line 364 stacked, and the second assembly line 370 can include a second lower line 372 and a second upper line 374 stacked.

Meanwhile, the light-emitting elements 380 can be provided in the assembly holes 352H respectively provided between the first portion 360a and the fifth portion 370b, between the fifth portion 370b and the second portion 360b, and between the second portion 360b and the fourth portion 370a.

In addition, the connection electrode 390 can be provided to correspond to each assembly hole 352H. The connection electrode 390 can be in contact with the first element electrode of the light-emitting element 380 and can be spaced apart from the second element electrode 382 of the light-emitting element 380. The connection electrode 390 can overlap and be in contact with the first and second assembly lines 360 and 370, and thus, the first element electrode of the light-emitting element 380 can be electrically connected to the first and second assembly lines 360 and 370.

The connection electrode 390 can have a ring shape substantially including an inner surface and an outer surface. The outer surface of the connection electrode 390 can have a smaller area than the assembly hole 352H and can be disposed in the assembly hole 352H, and the second element electrode 382 of the light-emitting element 380 can be disposed in the inner surface of the connection electrode 390.

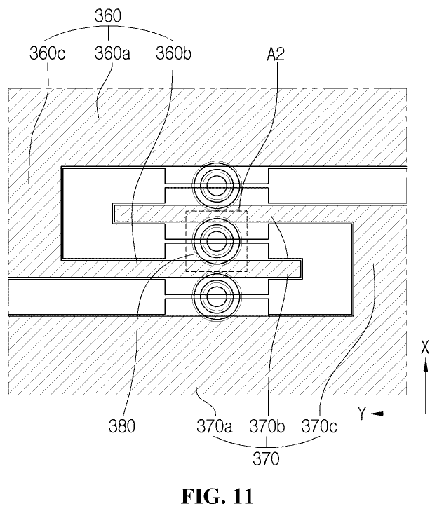

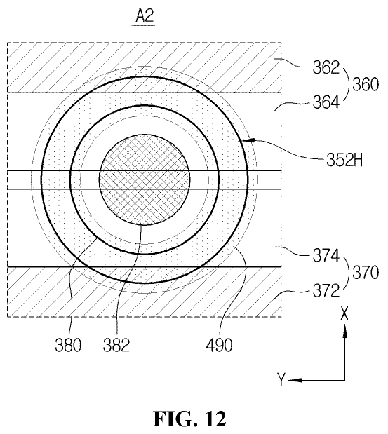

FIG. 11 is a schematic plan view of a display device according to a fourth embodiment of the present disclosure, and FIG. 12 is a schematic plan view enlarging area A2 of FIG. 11. The display device according to the fourth embodiment of the present disclosure can be a bottom emission type display device and can have substantially the same cross-sectional configuration as that of FIG. 6.

The display device according to the fourth embodiment of the present disclosure has substantially the same or similar configuration as that of the third embodiment, except for the connection electrode. The same parts as those of the third embodiment are designated by the same or similar reference signs, and explanation for the same parts can be shortened or omitted.

Referring to FIG. 11 and FIG. 12, each of the first and second assembly lines 360 and 370 can have substantially a U-like shape. Portions of the first and second assembly lines 360 and 370 can be alternately arranged along the first direction X, and the light-emitting elements 380 can be arranged in the first direction X.

The light-emitting elements 380 can be provided in the assembly holes 352H, respectively, and the connection electrode 490 can be provided to correspond to each assembly hole 352H. The connection electrode 490 can be in contact with the first element electrode of the light-emitting element 380 and can be in contact with the first and second assembly lines 360 and 370, so that the connection electrode 490 can electrically connect the first element electrode and the first and second assembly lines 360 and 370.

The connection electrode 490 can have a ring shape substantially including an inner surface and an outer surface. The outer surface of the connection electrode 490 can have a larger area than the assembly hole 352H, and the assembly hole 352H can be disposed in outer surface of the connection electrode 490. The second element electrode 382 of the light-emitting element 380 can be disposed in the inner surface of the connection electrode 490.

As such, the first and second assembly lines 360 and 370 according to the embodiments of the present disclosure can have various configurations, and the arrangement of the light-emitting element 380 can vary according to the configurations of the first and second assembly lines 360 and 370.

The display device according to aspects of the present disclosure can be configured by attaching the assembly substrate with the self-assembled light-emitting element and the array substrate with the thin film transistor, so that the transfer steps of the light-emitting element can be reduced or minimized, defects due to complex transfer steps can be decreased or avoided, and the manufacturing time and costs can be reduced or minimized. Accordingly, the manufacturing process of the display device can be optimized and the production energy consumption can be reduced or minimized.

In addition, according to aspects of the present disclosure, by using the assembly lines of the assembly substrate as a power line, a relatively high power voltage required for high resolution can be stably supplied, thereby preventing or minimizing a decrease in the image quality.

Further, according to aspects of the present disclosure, the amount of light output to the outside (e.g., of the display device) can be increased by using the electrode connecting the light-emitting element and the assembled line as a reflection electrode. Accordingly, power consumption can be reduced or minimizing by improving the efficiency and lifetime of the light-emitting element, thereby realizing low power consumption effectively and advantageously.

It will be apparent to those skilled in the art that various modifications and variations can be made in the display device and the method of manufacturing the same of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a first substrate;
a thin film transistor over an inner surface of the first substrate;
a second substrate spaced apart from the first substrate;
a light-emitting element over an inner surface of the second substrate facing the first substrate, and including a first element electrode and a second element electrode; and
a first assembly line and a second assembly line between the second substrate and the light-emitting element,
wherein the first element electrode of the light-emitting element is electrically connected to the first and second assembly lines, and the second element electrode of the light-emitting element is electrically connected to the thin film transistor.

2. The display device of claim 1, further comprising a connection electrode over the inner surface of the second substrate,
wherein the connection electrode is in contact with the first element electrode and is in contact with the first and second assembly lines.

3. The display device of claim 2, wherein the light-emitting element further includes a light-emitting layer between the first element electrode and the second element electrode, and
wherein the connection electrode overlaps a side surface of the light-emitting layer.

4. The display device of claim 3, wherein some of light emitted from the light-emitting layer is reflected by the connection electrode and is output to an outside of the display device through the second substrate.

5. The display device of claim 3, further comprising an insulation layer over the inner surface of the second substrate and having an assembly hole,
wherein the light-emitting element is disposed in the assembly hole of the insulation layer, and the connection electrode is spaced apart from a top surface of the insulation layer away from the second substrate.

6. The display device of claim 2, wherein the light-emitting element further includes a light-emitting layer between the first element electrode and the second element electrode, and
wherein the connection electrode is spaced apart from a side surface of the light-emitting layer.

7. The display device of claim 6, wherein some of light emitted from the light-emitting layer is reflected by the connection electrode and is output to an outside of the display device through the first substrate.

8. The display device of claim 6, further comprising an insulation layer over the inner surface of the second substrate and having an assembly hole,
wherein the light-emitting element is disposed in the assembly hole of the insulation layer, and the connection electrode is in contact with a top surface of the insulation layer away from the second substrate.

9. The display device of claim 6, further comprising a contact electrode between the light-emitting element and the thin film transistor,
wherein the contact electrode includes a transparent conductive material.

10. The display device of claim 2, wherein the connection electrode has a ring shape including an inner surface and an outer surface, and the second element electrode is disposed in the inner surface of the connection electrode.

11. The display device of claim 1, further comprising an adhesive layer between the first and second assembly lines and the light-emitting element.

12. The display device of claim 1, wherein the second element electrode is electrically connected to the thin film transistor through eutectic bonding by a bonding member.

13. A method of manufacturing a display device, the method comprising:
forming a thin film transistor over a first substrate;
forming a first assembly line and a second assembly line over a second substrate;
forming a second insulation layer over the first and second assembly lines, the second insulation layer having an assembly hole;
transferring a light-emitting element in the assembly hole, the light-emitting element including a first element electrode and a second element electrode;
forming a connection electrode contacting the first element electrode and the first and second assembly lines; and
attaching the first substrate provided with the thin film transistor and the second substrate provided with the connection electrode to each other,
wherein the first element electrode is electrically connected to the first and second assembly lines, and the second element electrode is electrically connected to the thin film transistor.

14. The method of claim 13, further comprising forming an adhesive layer between the first and second assembly lines and the light-emitting element.

15. The method of claim 14, wherein the forming of the adhesive layer is performed between the transferring of the light-emitting element and the forming of the connection electrode.

16. The method of claim 14, further comprising forming a third insulation layer covering side surfaces of the light-emitting element, the connection electrode, and the second insulation layer.

17. The method of claim 16, wherein the forming of the third insulation layer is performed between the forming of the connection electrode and the attaching of the first substrate and the second substrate.
